(19) United States
(12) Patent Application Publication
(10) Pub. No.: US 2025/0379021 A1
(43) Pub. Date: Dec. 11, 2025

(54) CHARGED PARTICLE BEAM IRRADIATION APPARATUS AND CHARGED PARTICLE BEAM IRRADIATION METHOD

(71) Applicant: NuFlare Technology, Inc., Yokohama-shi (JP)

(72) Inventors: Takanao TOUYA, Kawasaki-shi (JP); Hirofumi MORITA, Setagaya-ku (JP); Satoshi NAKAHASHI, Yokohama-shi (JP)

(73) Assignee: NuFlare Technology, Inc., Yokohama-shi (JP)

(21) Appl. No.: 19/218,728

(22) Filed: May 27, 2025

(30) Foreign Application Priority Data
Jun. 5, 2024 (JP) 2024-091691

(51) Int. Cl. H01J 37/04; H01J 37/14; H01J 37/147; H01J 37/21; H01J 37/24; H01J 37/317

(52) U.S. Cl. CPC H01J 37/045; H01J 37/14; H01J 37/1472; H01J 37/21; H01J 37/24; H01J 37/3177

(57) ABSTRACT

In one embodiment, a charged particle beam irradiation apparatus includes a stopping aperture substrate blocking the beam which has been deflected by a blanker, a front stage electrode disposed upstream of the stopping aperture substrate in a traveling direction of the beam, and an electric potential control circuit generating an electric field in a direction from the stopping aperture substrate to the front stage electrode. An inner diameter d of the front stage electrode is determined based on a distance L1 from an upper end of the front stage electrode to the stopping aperture substrate, a distance r1 from a center of the beam to a position at which the stopping aperture substrate is hit by the beam which has undergone the blanking deflection, and a spread radius r2 of secondary electron at the upper end of the front stage electrode.

### CROSS REFERENCE TO RELATED APPLICATION

This application is based upon and claims benefit of priority from the Japanese Patent Application No. 2024-91691, filed on Jun. 5, 2024, the entire contents of which are incorporated herein by reference.

### FIELD

The present invention relates to a charged particle beam irradiation apparatus and a charged particle beam irradiation method.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. The high-precision original pattern is written by using an electron-beam writing apparatus, in which a so-called electron-beam lithography technique is employed.

For example, there is a writing apparatus using a multi-beam. Compared to a single electron beam writing, many beams can be irradiated at one time using a multi-beam, thus the throughput can be significantly improved. In a multi-beam writing apparatus, for example, an electron beam emitted from an electron gun is passed through an aperture array substrate having a plurality of openings to form a multi-beam, and each beam is individually blanking controlled by a blanking aperture array substrate. A blanking deflected beam by the blanking aperture array substrate is blocked by a stopping aperture substrate, and an undeflected beam passes through an opening in the stopping aperture

When a blanking-deflected beam is blocked by the stopping aperture substrate, secondary electrons (including reflected electrons) are emitted from the stopping aperture substrate. The beam is deflected by the electric field of a cloud of secondary electrons, and the beam irradiation position on a sample is displaced, thus materials producing a less amount of emitted secondary electrons have been used for the stopping aperture substrate.

However, reduction of the secondary electrons emitted from stopping aperture substrate has a limit. In addition, a secondary electron emission rate varies with time due to deterioration over time of the stopping aperture substrate material. When the beam current is increased to improve the throughput, the amount of emitted secondary electrons increases in proportion to the beam current, thus the electric field of the secondary electrons has a significant effect on the beam.

### BRIEF DESCRIPTION OF THE DRAWINGS

FIG. 1 is a schematic configuration view of a writing apparatus according to an embodiment of the present invention.

FIG. 2 is a plan view of a shaping aperture array substrate.

FIG. 3 is a schematic view of secondary electrons emitted from a stopping aperture substrate.

FIG. 4 is a view for explaining the inner diameter of a front stage electrode.

### DETAILED DESCRIPTION

In one embodiment, a charged particle beam irradiation apparatus includes a charged particle source generating and emitting a beam, a blanker performing blanking deflection on the beam, a stopping aperture substrate blocking the beam which has been deflected by the blanker to achieve a beam-off state, a deflector deflecting the beam which has passed through the stopping aperture substrate, and irradiating a predetermined position on the substrate with the beam, a front stage electrode disposed upstream of the stopping aperture substrate in a traveling direction of the beam, and an electric potential control circuit generating an electric field in a direction from the stopping aperture substrate to the front stage electrode by applying a predetermined electric potential to at least one of the stopping aperture substrate and the front stage electrode so that an electric potential of the front stage electrode is higher than an electric potential of the stopping aperture substrate. An inner diameter d of the front stage electrode is determined based on a distance L1 from an upper end of the front stage electrode to the stopping aperture substrate, a distance r1 from a center of the beam to a position at which the stopping aperture substrate is hit by the beam which has undergone the blanking deflection, and a spread radius r2 of secondary electron at the upper end of the front stage electrode.

Hereinafter, in an embodiment of the present invention, a configuration using an electron beam as an example of a charged particle beam will be described. The charged particle beam is not limited to the electron beam. For example, the charged particle beam may be an ion beam. In the embodiment, a multi-beam writing apparatus using multi-electron beam as an example of a charged particle beam irradiation apparatus will be described. However, the multi-charged particle beam irradiation apparatus is not limited to the multi-beam writing apparatus, and the embodiment may be applied to a multi-beam inspection apparatus.

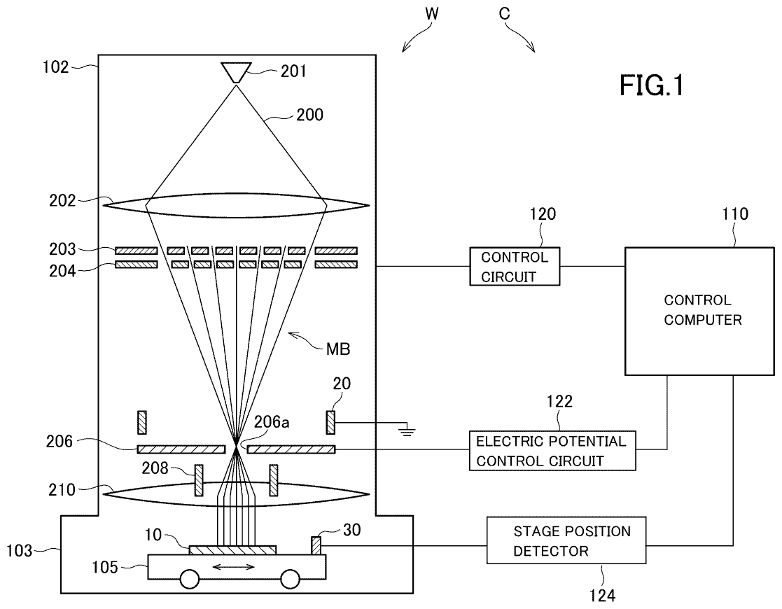

FIG. 1 is a schematic configuration view of a multi-beam writing apparatus according to an embodiment of the present invention. As illustrated in FIG. 1, the multi-beam writing apparatus includes a writer W and a controller C. The writer W includes an electron optical column 102 and a writing chamber 103. In the electron optical column 102, an electron source 201, an illumination lens 202, a shaping aperture array substrate 203, a blanking aperture array substrate 204, a front stage electrode 20, a stopping aperture substrate 206, a deflector 208, and an objective lens 210 that constitute an electron optical system of the multi-beam writing apparatus are disposed.

In the writing chamber 103, an XY stage 105 movable in the XY direction is disposed. The XY stage 105 may be movable in the Z direction. On the XY stage 105, a substrate 10 as a writing target is disposed. The substrate 10 may refer to an exposure mask when a semiconductor device is fabricated, and a semiconductor substrate (silicon wafer) on which a semiconductor device is fabricated. In addition, the substrate 10 may refer to mask blanks coated with resist, on which nothing has been written.

On the XY stage 105, a mirror 30 for measuring the stage position is disposed.

The controller C includes a control computer 110, a control circuit 120, an electric potential control circuit 122 and a stage position detector 124. The stage position detector 124 emits a laser, receives light reflected from the mirror 30, and detects the position of the XY stage 105 by the principle of laser interferometry.

FIG. 1 illustrates the components necessary for explaining the embodiment, and other components are not illustrated.

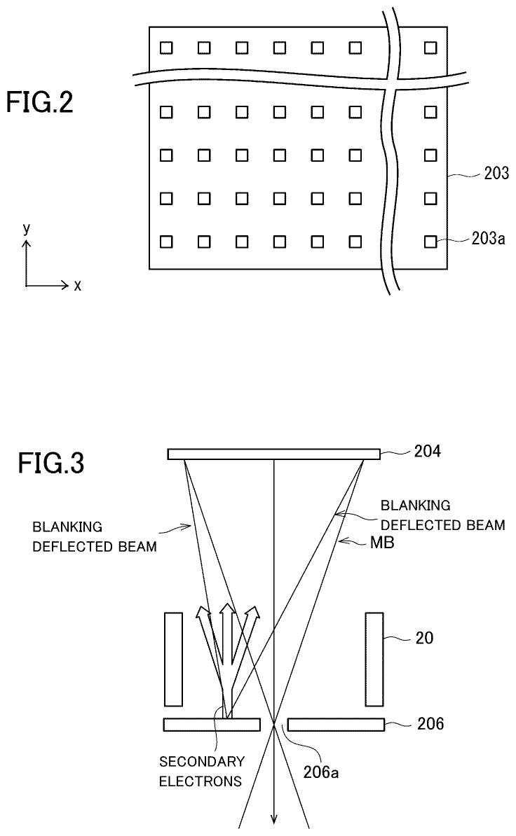

FIG. 2 is a conceptual view of the configuration of the shaping aperture array substrate 203. In FIG. 2, in the shaping aperture array substrate 203, openings (first openings) 203a in p vertical (y direction) columns×q horizontal (x direction) rows (p, q≥2) are formed in a matrix form with a predetermined arrangement pitch. For example, the openings 203a in 512 columns x 512 rows are formed. The openings 203a are formed in rectangular shapes having the same dimensions. The openings 203a may be circular. Part of an electron beam 200 passes through a corresponding one of these multiple openings 203a, thereby forming a multi-beam MB.

The blanking aperture array substrate 204 is provided below the shaping aperture array substrate 203, and passage holes (second openings) are formed corresponding to the arranged positions of the openings 203a of the shaping aperture array substrate 203. A blanker consisting of a set of two paired electrodes is disposed in each passage hole. One electrode of the blanker is fixed to the ground electric potential, and the other electrode is switched to an electric potential different from the ground electric potential. Electron beams passing through respective passage holes are each independently deflected by a voltage applied to a corresponding one of blankers. In this manner, multiple blankers perform blanking deflection on corresponding beams in the multi-beam MB which has passed through the multiple openings 203a of the shaping aperture array substrate 203.

The electron beam 200 emitted from the electron source 201 (emitter) is refracted by the illumination lens 202, and illuminates the entire shaping aperture array substrate 203. The electron beam 200 illuminates an area including the multiple (all) openings 203a. Part of the electron beam 200 passes through the multiple openings 203a of the shaping aperture array substrate 203, thereby forming a multi-beam MB including multiple individual beams. The multi-beam MB passes through corresponding blankers of the blanking aperture array substrate 204. The blankers each perform blanking control on an individual beam so that the beam is in ON state for a set writing time (irradiation time).

The multi-beam MB which has passed through the blanking aperture array substrate 204 travels to an opening 206a (third opening) formed in the center of the stopping aperture substrate 206 by the refraction of the illumination lens 202. The multi-beam MB forms a crossover at the height position of the opening 206a.

Each beam deflected by a blanker of the blanking aperture array substrate 204 deviates in position from the opening 206a of the stopping aperture substrate 206, and is blocked by the stopping aperture substrate 206. In contrast, each beam not deflected by a blanker of the blanking aperture array substrate 204 passes through the opening 206a of the stopping aperture substrate 206. In this manner, the stopping aperture substrate 206 blocks the beams which have been deflected to achieve a beam OFF state by respective blankers.

The beam for one shot is formed by the beam which has passed through the stopping aperture substrate 206 since beam-ON until beam-OFF is achieved. Each beam in the multi-beam MB which has passed through the stopping aperture substrate 206 becomes an aperture image with a desired reduction ratio of an opening 203a of the shaping aperture array substrate 203 by the objective lens 210, and is adjusted in focus on the substrate 10. The beams (the entire multi-beam) which have passed through the stopping aperture substrate 206 are collectively deflected by the deflector 208 in the same direction, and are irradiated to respective irradiation positions of the beams on the substrate 10.

For example, when the XY stage 105 is continuously moved, the irradiation position of each beam is controlled by the deflector 208 so that the irradiation position follows the movement of the XY stage 105. The multi-beam MB irradiated at once is ideally arranged with a pitch which is the product of the arrangement pitch of the multiple openings 203a of the shaping aperture array substrate 203 and the above-mentioned desired reduction ratio. The writing apparatus performs a writing operation by a raster scan method by which a shot beam is sequentially irradiated continuously, and when a desired pattern is written, unnecessary beams are controlled at beam OFF by the blanking control.

In this writing apparatus, when a blanking-deflected beam is blocked by the stopping aperture substrate 206, secondary electrons are emitted from the stopping aperture substrate 206, and the secondary electrons have an effect on the beam irradiation position.

Thus, in this embodiment, the front stage electrode 20 set to the ground electric potential is disposed above (upstream in the traveling direction of the multi-beam) the stopping aperture substrate 206, and the electric potential control circuit 122 applies a negative electric potential to the stopping aperture substrate 206.

Consequently, an electric field is generated in the direction from the stopping aperture substrate 206 to the front stage electrode 20, thus as illustrated in FIG. 3, the secondary electrons emitted from the stopping aperture substrate 206 are accelerated upstream of the optical path, and moved upward. Since the secondary electron density is reduced, the effect of the secondary electrons on the beam can be reduced, and beam irradiation position accuracy can be improved. Because the secondary electrons are accelerated and moved upward by electric field control, the effect varies little, and has a small variation with lapse of time.

The level of electric potential to be given by the electric potential control circuit 122 is determined based on the beam current of the multi-beam, the material for the stopping aperture substrate 206, and the space between the stopping aperture substrate 206 and the front stage electrode 20.

The material for the stopping aperture substrate 206 is not limited to a specific one, and e.g., Ta may be used. The shape of the stopping aperture substrate 206 and the opening 206a is e.g., circular.

The shape of the front stage electrode 20 is not limited to a specific one, and preferably has a rotationally symmetric shape with respect to the trajectory central axis (optical axis) of the multi-beam. For example, a cylindrical electrode may be used. The material for the front stage electrode 20 is not limited to a specific one, and e.g., Ti may be used.

When many of secondary electrons emitted from the stopping aperture substrate 206 collide with the front stage electrode 20, contamination (dirt) is formed on the electrode surface. The contamination is charged due to the secondary electrons and reflected electrons, and the multi-beam is deflected by a generated electric field, causing a problem that the beam position is unstable. In order to prevent formation of contamination, it is necessary that the secondary electrons emitted from the stopping aperture substrate 206 move upward through the front stage electrode 20 without colliding with the inner peripheral surface of the front stage electrode 20, or the ratio of the secondary electrons that move upward be increased. Thus, the inner diameter d of the front stage electrode 20 is given by the value expressed by the following mathematical expression.

In the following mathematical expression, r1 is the distance from the center of the opening 206a of the stopping aperture substrate 206 to the position at which the stopping aperture substrate 206 is hit by the beam which has undergone blanking deflection. r2 is the spread radius of secondary electron at the upper end of the front stage electrode 20.

The inner diameter d>2×(r1+r2)

The spread radius r2 of secondary electron is given by the electrode radius for which the ratio of secondary electrons that collide with the front stage electrode 20 is less than or equal to a predetermined value. For example, the spread radius r2 of secondary electron is given by the electrode radius for which the ratio of secondary electrons with 20 eV or less that collide with the front stage electrode 20 is less than or equal to 50%.

It is possible to calculate r1 by trajectory simulation of the multi-beam (primary beam). r1 may be determined by measuring the amount of movement of beam due to blanking deflection on the stopping aperture substrate 206 in an actual apparatus. It is possible to calculate r2 by trajectory simulation of the secondary electrons emitted from the stopping aperture substrate 206. Alternatively, r2 may be calculated by the method described below.

The energy of secondary electron has a distribution which depends on the material (the material for the stopping aperture substrate 206) for the member to be irradiated, and normally, in the metal material (for example, Ta) that constitutes the aperture substrate, the ratio of the secondary electrons with 5 eV or less to the secondary electrons with 20 eV or less exceeds 50%. Thus, attention is paid to the secondary electrons with an energy of 5 eV emitted from the surface of the stopping aperture substrate 206 in a lateral direction (direction perpendicular to the optical axis, emission angle of 90 degrees), and let r2 be the spread radius. Because all the secondary electrons with an energy of 5 eV or less do not collide with the front stage electrode 20, the ratio of the secondary electrons that collide with the front stage electrode 20 to the secondary electrons with 20 eV or less is lower than or equal to 50%. For the secondary electrons with an energy exceeding 5 eV, the secondary electrons with an emission angle less than a certain degree do not collide with the front stage electrode 20, thus the ratio of the secondary electrons that collide is further reduced.

Therefore, assuming that the value (secondary electron energy representative value) that represents the energy of secondary electron is 5 eV, the spread radius r2 may be determined based on the secondary electrons emitted with an energy of 5 eV in a lateral direction from the surface of the stopping aperture substrate 206.

Under the assumption that the objective lens 210 is a magnetic field lens, and the front stage electrode 20 is in the magnetic field of the objective lens 210, the secondary electrons move helically due to the magnetic field, thus the spread radius r2 of secondary electron is the secondary electron Larmor radius calculated based on the minimum magnetic field and the energy within the distance L1 from the upper end of the front stage electrode 20 to the stopping aperture substrate 206.

Let B_{MIN} (unit T) be a minimum magnetic field, and V₁ (unit eV) be the value (secondary electron energy representative value) that represents the energy of secondary electron, then the spread radius r2 (unit m) of secondary electron is calculated by the following Expression (1). Note that m is the mass (unit kg) of an electron, and e is the electric charge quantity (unit C) of an electron.

$$r 2 = \sqrt{\frac{2 {mV}_{1}}{e}} \frac{1}{{B}_{MIN}} \qquad ( 1 )$$

The minimum magnetic field B_{MIN} may be determined by numerical computation, or determined by magnetic field measurement using Hall elements and the like. The secondary electron energy representative value V₁ may be normally 5 eV.

Under the assumption (including that the objective lens 210 is an electrostatic lens) that the front stage electrode 20 is outside the magnetic field of the objective lens 210, the trajectory of secondary electron is estimated as a straight line from the emission angle and energy of secondary electron, and the spread radius r2 of secondary electron is given by the electrode radius for which the ratio of secondary electron that collide with the front stage electrode 20 is less than or equal to a predetermined value.

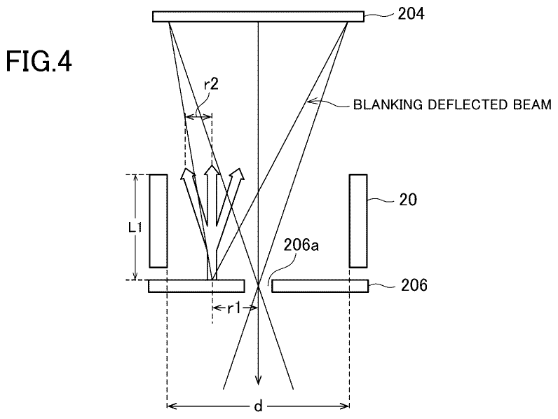

When the front stage electrode 20 is cylindrical as illustrated in FIG. 4, the secondary electrons emitted from the stopping aperture substrate 206 are accelerated, at a location relatively close to the emission position, to an energy corresponding to the potential difference between the front stage electrode 20 and the stopping aperture substrate 206, thus the trajectory of the secondary electrons is generally approximated to a straight line. Let V₁ be the secondary electron energy representative value, and V₀ (unit V) be the potential difference between the front stage electrode 20 and the stopping aperture substrate 206, then r2 is calculated by the following Expression (2).

$$r 2 = L 1 \sqrt{\frac{{V}_{1}}{{V}_{0}}} \qquad ( 2 )$$

When the shape of the front stage electrode 20 is not cylindrical, the straight-line approximation gives a slight error; however, Expression (2) may be used.

Since the energy (from 1 eV or less to several 10 eV) of secondary electron is extremely smaller than the energy (e.g., 50 kV=50000 eV) of a primary beam, even at a location where the magnetic field attenuates to be low, the effect on the secondary electrons may remain. Like this, it may be difficult to simply determine from the disposition and magnetic field intensity whether the secondary electrons generated in the front stage electrode 20 are affected by the lens magnetic field. Thus, both Expressing (1) assuming exposure to the magnetic field and Expressing (2) assuming non-exposure to the magnetic field are calculated, and r2 may be set to the smaller value.

The center of the opening 206a of the stopping aperture substrate 206 and the axis of the cylindrical front stage electrode 20 are preferably located on the trajectory central axis of the multi-beam.

In the above embodiment, the configuration has been described in which the front stage electrode 20 is set to the ground electric potential, and a negative electric potential is applied to the stopping aperture substrate 206; however, it is sufficient that an electric field be generated in the direction from the stopping aperture substrate 206 to the front stage electrode 20 by setting the electric potential of the front stage electrode 20 to be higher than the electric potential of the upper surface of the stopping aperture substrate 206. For example, the stopping aperture substrate 206 may be set to the ground electric potential, and the electric potential control circuit 122 may apply a positive electric potential to the front stage electrode 20.

Alternatively, the electric potential control circuit 122 may apply a positive electric potential to the front stage electrode 20, and apply a negative electric potential to the stopping aperture substrate 206.

In the above embodiment, the apparatus using a multi-beam has been described; however, the invention is applicable to an apparatus using a single beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam irradiation apparatus comprising:
a charged particle source generating and emitting a beam;
a blanker performing blanking deflection on the beam;
a stopping aperture substrate blocking the beam which has been deflected by the blanker to achieve a beam-off state;
a deflector deflecting the beam which has passed through the stopping aperture substrate, and irradiating a predetermined position on the substrate with the beam;
a front stage electrode disposed upstream of the stopping aperture substrate in a traveling direction of the beam; and
an electric potential control circuit generating an electric field in a direction from the stopping aperture substrate to the front stage electrode by applying a predetermined electric potential to at least one of the stopping aperture substrate and the front stage electrode so that an electric potential of the front stage electrode is higher than an electric potential of the stopping aperture substrate,
wherein an inner diameter d of the front stage electrode is determined based on a distance L1 from an upper end of the front stage electrode to the stopping aperture substrate, a distance r1 from a center of the beam to a position at which the stopping aperture substrate is hit by the beam which has undergone the blanking deflection, and a spread radius r2 of secondary electron at the upper end of the front stage electrode.

2. The charged particle beam irradiation apparatus according to claim 1,
wherein the inner diameter d of the front stage electrode satisfies d>2×(r1+r2).

3. The charged particle beam irradiation apparatus according to claim 2, further comprising
an objective lens that is a magnetic field lens,
wherein let B_{MIN} be a minimum magnetic field within the distance L1 from the upper end of the front stage electrode to the stopping aperture substrate, Vi be a secondary electron energy representative value, m be a mass of an electron, and e be an electric charge quantity of an electron, then the radius r2 is calculated by
$$r 2 = \sqrt{\frac{2 {mV}_{1}}{e}} \frac{1}{{B}_{MIN}}$$

4. The charged particle beam irradiation apparatus according to claim 2,
wherein let L1 be the distance from the upper end of the front stage electrode to the stopping aperture substrate, V₀ be a potential difference between the front stage electrode and the stopping aperture substrate, V₁ be a secondary electron energy representative value, then the radius r2 is calculated by
$$r 2 = L 1 \sqrt{\frac{{V}_{1}}{{V}_{0}}}$$

5. The charged particle beam irradiation apparatus according to claim 2,
further comprising
an objective lens that is a magnetic field lens,
wherein let L1 be the distance from the upper end of the front stage electrode to the stopping aperture substrate, B_{MIN} be a minimum magnetic field within the distance L1 from the upper end of the front stage electrode to the stopping aperture substrate, V₀ be a potential difference between the front stage electrode and the stopping aperture substrate, V₁ be a secondary electron energy representative value, m be a mass of an electron, and e be an electric charge quantity of an electron, then the radius r2 is a smaller one of following values: a value calculated by
$$r 2 = \sqrt{\frac{2 {mV}_{1}}{e}} \frac{1}{{B}_{MIN}}$$
and a value calculated by
$$r 2 = L 1 \sqrt{\frac{{V}_{1}}{{V}_{0}}}$$

6. The charged particle beam irradiation apparatus according to claim 1,
wherein the electric potential control circuit applies a negative electric potential to the stopping aperture substrate, and the front stage electrode is set to a ground electric potential.

7. The charged particle beam irradiation apparatus according to claim 1,
wherein the electric potential control circuit applies a positive electric potential to the front stage electrode, and the stopping aperture substrate is set to a ground electric potential.

8. The charged particle beam irradiation apparatus according to claim 1,
wherein the electric potential control circuit applies a positive electric potential to the front stage electrode, and applies a negative electric potential to the stopping aperture substrate.

9. The charged particle beam irradiation apparatus according to claim 1,
wherein the front stage electrode is cylindrical.

10. The charged particle beam irradiation apparatus according to claim 9,
wherein a center of an opening of the stopping aperture substrate and an axis of the front stage electrode are located on a beam trajectory central axis.

11. A charged particle beam irradiation method comprising:
generating a beam using a charged particle source;
performing blanking deflection on the beam using a blanker;
blocking, by a stopping aperture substrate, the beam which has been deflected by the blanker to achieve a beam-off state;
deflecting the beam which has passed through the stopping aperture substrate by a deflector, and irradiating a predetermined position on the substrate with the beam; and
generating an electric field in a direction from the stopping aperture substrate to the front stage electrode by applying a predetermined electric potential to at least one of the stopping aperture substrate and the front stage electrode so that an electric potential of the front stage electrode disposed upstream of the stopping aperture substrate in a traveling direction of the beam is higher than an electric potential of the stopping aperture substrate,
wherein an inner diameter d of the front stage electrode is determined based on a distance L1 from an upper end of the front stage electrode to the stopping aperture substrate, a distance r1 from a center of the beam to a position at which the stopping aperture substrate is hit by the beam which has undergone the blanking deflection, and a spread radius r2 of secondary electron at the upper end of the front stage electrode.

12. The charged particle beam irradiation method according to claim 11,
wherein the inner diameter d of the front stage electrode satisfies d>2×(r1+r2).

13. The charged particle beam irradiation method according to claim 12, further comprising adjusting a focus of the beam on the substrate using an objective lens that is a magnetic field lens,
wherein let B_{MIN} be a minimum magnetic field within the distance L1 from the upper end of the front stage electrode to the stopping aperture substrate, V₁ be a secondary electron energy representative value, m be a mass of an electron, and e be an electric charge quantity of an electron, then the radius r2 is calculated by
$$r 2 = \sqrt{\frac{2 {mV}_{1}}{e}} \frac{1}{{B}_{MIN}}$$

14. The charged particle beam irradiation method according to claim 12,
wherein let L1 be the distance from the upper end of the front stage electrode to the stopping aperture substrate, V₀ be a potential difference between the front stage electrode and the stopping aperture substrate, V₁ be a secondary electron energy representative value, then the radius r2 is calculated by
$$r 2 = L 1 \sqrt{\frac{{V}_{1}}{{V}_{0}}}$$

15. The charged particle beam irradiation method according to claim 12, further comprising adjusting a focus of the beam on the substrate using an objective lens that is a magnetic field lens,
wherein let L1 be the distance from the upper end of the front stage electrode to the stopping aperture substrate, B_{MIN} be a minimum magnetic field within the distance L1 from the upper end of the front stage electrode to the stopping aperture substrate, V₀ be a potential difference between the front stage electrode and the stopping aperture substrate, V₁ be a secondary electron energy representative value, m be a mass of an electron, and e be an electric charge quantity of an electron, then the radius r2 is a smaller one of following values: a value calculated by
$$r 2 = \sqrt{\frac{2 m {V}_{1}}{e}} \frac{1}{{B}_{MIN}}$$
and a value calculated by
$$r 2 = L 1 \sqrt{\frac{{V}_{1}}{{V}_{0}}}$$

16. The charged particle beam irradiation method according to claim 11,
wherein a negative electric potential is applied to the stopping aperture substrate, and the front stage electrode is set to a ground electric potential.

17. The charged particle beam irradiation method according to claim 11,
wherein a positive electric potential is applied to the front stage electrode, and the stopping aperture substrate is set to a ground electric potential.

18. The charged particle beam irradiation method according to claim 11,
wherein a positive electric potential is applied to the front stage electrode, and a negative electric potential is applied to the stopping aperture substrate.
